(19) United States
(12) Patent Application Publication
(10) Pub. No.: US 2022/0011748 A1
(43) Pub. Date: Jan. 13, 2022

(54) METHOD AND DEVICE FOR AN INDUSTRIAL SYSTEM

(71) Applicant: Robert Bosch GmbH, Stuttgart (DE)

(72) Inventors: Felix Milo Richter, Heidenheim (DE); Maksym Lefarov, Stuttgart (DE)

(21) Appl. No.: 17/365,851

(22) Filed: Jul. 1, 2021

(30) Foreign Application Priority Data
Jul. 7, 2020 (DE) 102020208473.4

(51) Int. Cl. G05B 19/4155

(52) U.S. Cl. CPC G05B 19/4155; G05B 2219/32304

(57) ABSTRACT

A method for an industrial system. The method includes: ascertaining a representation of the industrial system, the ascertainment of the representation including: selecting a first state of the representation, selecting, based on the first state, at least one machining order from a plurality of machining orders as a function of the first state of the representation and as a function of at least one previously ascertained recommendation, and ascertaining a second state as a subsequent state of the first state via a simulation of the second state as a function of the at least one selected machining order and as a function of the first state; and ascertaining a manufacturing schedule for the industrial system as a function of the ascertained representation.

### CROSS REFERENCE

The present application claims the benefit under 35 U.S.C. § 119 of German Patent Application No. DE 102020208473.4 filed on Jul. 7, 2020, which is expressly incorporated herein by reference in its entirety.

### FIELD

The present invention relates to a method and to a device for an industrial system.

### BACKGROUND INFORMATION

The assignment and ordering of machining orders to industrial executing machining resources is referred to as scheduling. The output of a scheduling algorithm is referred to as a “schedule” or “guideline” or as a manufacturing schedule. The optimization of the throughput or of the utilization of machining resources is a challenge and has the potential for large cost savings.

The scheduling presently takes place frequently using handcrafted scheduling rules that have been designed by experts in the industry, for example, by assigning orders in ascending order of their processing time or by favoring orders whose completion date is nearest.

### SUMMARY

The problem underlying the present invention is solved by a method according to example embodiments of the present invention, by a device according to example embodiments of the present invention, and by a use according to example embodiments of the present invention. Advantageous refinements of the present invention are disclosed herein.

A first aspect of the present invention relates to a method for an industrial system. In accordance with an example embodiments of the present invention, the method includes: ascertaining a representation of the industrial system, the ascertainment of the representation including: selecting a first state of the representation, choosing, based on the first state, at least one machining order from a plurality of machining orders as a function of the first state of the representation and as a function of at least one previously ascertained recommendation, ascertaining a second state as a subsequent state of the first state via a simulation of the second state as a function of the at least one chosen machining order and as a function of the first state; and ascertaining a manufacturing schedule for the industrial system as a function of the ascertained representation.

On the one hand, an adaptive ascertainment of the states is advantageously made possible by the previously ascertained recommendation. On the other hand, the interpretability of the result in the form of states improves with knowledge of the previously ascertained recommendation of an expert. This means that domain knowledge of experts is incorporated in the ascertainment of the manufacturing schedule. At the same time, an optimized result is made possible by the application of the representation in terms of a search tree. Consequently, the acceptance of the method is increased as a result of the application of the expert knowledge and, at the same time, an automated optimized ascertainment of the manufacturing schedule is provided.

In one advantageous example embodiment of the present invention, the method includes: operating the industrial system as a function of the ascertained manufacturing schedule.

The ascertained manufacturing schedule advantageously makes it possible to achieve an improved result in the execution of the machining orders.

In one advantageous example embodiment of the present invention, the method includes: ascertaining that an abort criterion for operating the industrial system is met; ascertaining a second representation with the state of the industrial system when meeting the abort criterion as a start state of the second representation; ascertaining a second manufacturing schedule for the industrial system as a function of the ascertained second representation; and operating the industrial system as a function of the second manufacturing schedule.

In this way, an incremental optimization and readjustment of the production may advantageously take place during ongoing operation.

In one advantageous example embodiment of the present invention, the ascertainment of the representation of the industrial system includes: assigning the selected at least one machining order to a processing resource of the representation of the industrial system as a function of the state of the processing resource of the representation in the first state.

The assignment is advantageously carried out as a function of the state of the processing resource, a consideration of the respective state of the processing resource such as, for example, occupied or free, is thereby taken into account.

In one advantageous example embodiment of the present invention, the ascertainment of the representation of the industrial system includes: return of the result of the simulation along the selected states.

The return advantageously only takes place when the work steps, i.e., the plurality of machining orders, are processed. This provides a possible path for ascertaining the manufacturing schedule, for which a full execution of the plurality of machining orders is ensured.

In one advantageous example embodiment of the present invention, the ascertainment of the representation of the industrial system includes: reducing the weighting of the previously ascertained recommendation when selecting the at least one machining order with the increasing number of simulations of the respective state of the representation.

The assignment rule is established manually, for example, with the aid of expert knowledge. In this way, this expert rule helps to avoid inferior actions in terms of the selection and assignment of machining orders at the beginning of the search. By reducing the weighting, the Monte-Carlo method gains in importance, where the convergence is ensured. Due to the assignment rule at the start of the search, a positive result is more quickly achieved without losing the attractive properties of the Monte Carlo method.

In one advantageous example embodiment of the present invention, the selection of the machining order includes: selecting the machining order from the plurality of machining orders as a function of the previously ascertained recommendation and as a function of a criterion, the criterion including at least: an increased number of simulations carried out; an increased average total reward.

A decision criterion for selecting the action or the machining order is advantageously provided with the aid of the criterion.

In one advantageous example embodiment of the present invention, the ascertained states of the representation are part of a Monte Carlo search tree.

The convergence of the solutions and the ascertainment of an optimized manufacturing schedule are advantageously achieved with the aid of the design of a Monte Carlo search tree.

One second aspect of the present invention relates to a device for an industrial system, which is configured to ascertain a representation of the industrial system. In accordance with an example embodiment of the present invention, the ascertainment of the representation includes: selecting a first state of the representation, selecting, based on the first state, at least one machining order from a plurality of machining orders as a function of the first state of the representation and as a function of at least one previously ascertained recommendation, and ascertaining a second state as a subsequent state of the first state via a simulation of the second state as a function of the at least one selected machining order and as a function of the first state; and ascertaining a manufacturing schedule for the industrial system as a function of the ascertained representation. The device is configured to carry out the method(s) disclosed herein.

One further aspect of the present invention relates to a use of the method according to the first aspect or to a use of the device according to the second aspect.

### BRIEF DESCRIPTION OF THE DRAWINGS

FIG. 1 schematically shows a flowchart for ascertaining a manufacturing schedule, in accordance with an example embodiment of the present invention.

FIG. 2 schematically shows a block diagram including a device and an industrial system, in accordance with an example embodiment of the present invention.

### DETAILED DESCRIPTION OF EXAMPLE EMBODIMENTS

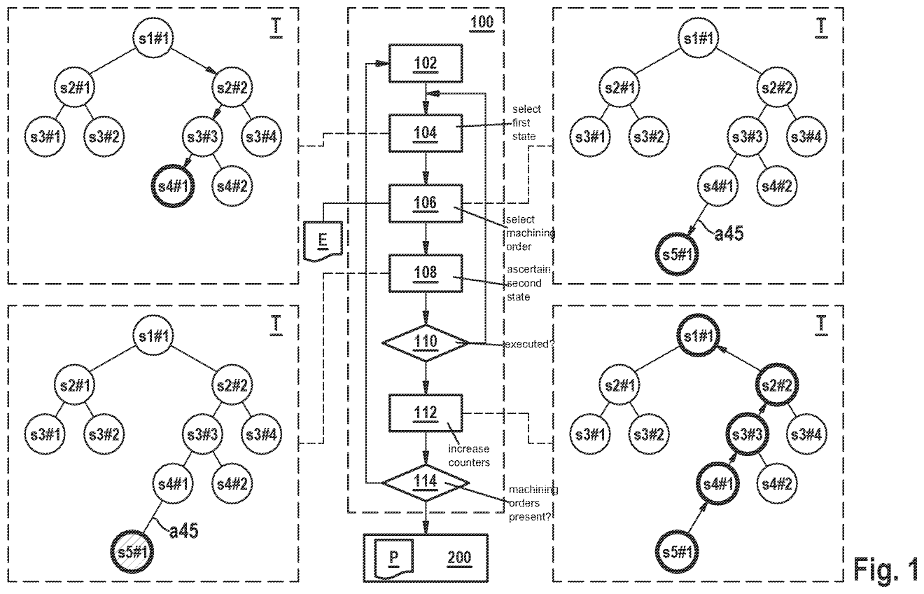

FIG. 1 schematically shows a flowchart for ascertaining a manufacturing schedule P for an industrial system. A representation T, in particular a Monte Carlo search tree, of the industrial system is ascertained in a step 100, the ascertainment of representation T including a multiple execution of subsequent steps 104 through 114 based on a start state s1#1 in a loop. Step 104 includes selecting first state s4#1 of representation T. The ascertained states of representation T are, for example, part of a Monte Carlo search tree.

Step 106 includes selecting, based on first state s4#1, at least one machining order a45, which is also referable to as a job, from a plurality of machining orders, each of which implies a start of a processing of a machining order on a subsystem of the industrial system, i.e., of a processing resource of the industrial system, in a subsequent state as a function of first state s4#1 of representation T and as function of at least one previously ascertained recommendation E, which has been generated, for example, through expert knowledge. Previously ascertained recommendation E is also referable to as a dispatching rule. Previously ascertained recommendation E includes, for example, a ranking, i.e., a weighting on the basis of the present possible machining orders. Thus, weightings are ascertained for the present possible machining orders, and the machining order is subsequently selected which has the highest or lowest weighting. Recommendation E includes, for example, the instruction to always select the job/machining order having the shortest processing time.

The selection in step 106 of machining order a45 includes selecting the machining order a45 from the plurality of machining orders as a function of previously ascertained recommendation E and as a function of a criterion, the criterion including at least: an increased number of carried out simulations in the leaf orientation, the number in first state s4#1 being stored; an increased average total reward.

A higher average total reward is represented by Q(s, a) of equation 1. Equation 1 ascertains the total score, a, representing a machining order or an action, Q(s, a) representing the exploitation term and the average total reward, which the algorithm has obtained up to this point by carrying out machining order a in state s. The root represents the exploration term. n(s) denotes how often the algorithm has already visited the state s. n(s, a) denotes how often the algorithm has selected machining order a in state s. 1/duration(a) corresponds to recommendation E, i.e., to the expert rule and denotes, for example, how long the processing of machining order a lasts, recommendation E preferring temporally shorter processing times and thus corresponding machining orders a.

$${a}_{selected} = arg {max}_{a} Q ( s , a ) + α \cdot \sqrt{log ( \frac{n ( s )}{n ( s , a )} )} + β \cdot \frac{1}{duration ( a )} \qquad ( 1 )$$

Either machining order a having the highest number of simulations is selected, i.e., n(s, a) in the above equation. Or, alternatively, machining order a having the maximum Q(s, a) value, i.e., the one having the highest average total reward, is selected.

Equation 1 is not readily applicable in states s, in which not all possible actions have been tested at least once. For each action a not yet tested, n(s4#1, a)=0, and thus would be divided in the root by 0. Instead, in attained states in which not all actions have been tested, one of actions a not yet tested is selected. Which of untested actions a is selected is determined, for example, by expert rule E: selecting the best action a according to expert rule E among actions a not yet tested.

In order to gradually reduce the influence of the recommendation term, i.e., the expert rule, n(s) is incorporated in the denominator according to equation 2.

$${a}_{selected} = arg {max}_{a} Q ( s , a ) + α \cdot \sqrt{log ( \frac{n ( s )}{n ( s , a )} )} + β \cdot \frac{1}{duration ( a ) \cdot n ( s )} \qquad ( 2 )$$

Ascertainment 100 of representation T of the industrial system includes in step 106 an assignment of the selected at least one machining order a45 to a processing resource R1; R2 of representation T of the industrial system as a function of the state of processing resource R1; R2 of representation T in first state s4#1. In first state s4#1, it is indicated, for example, that one of the machines or one of the processing resources is free, whereby a categorization of the machining order in the subsequent state, i.e., in second state s5#1, and thus the assignment, may take place.

Step 108 includes an ascertainment of a second state s5#1 as a subsequent state of first state s4#1 via a simulation of second state s5#1, during a simulation phase as a function of a simulated execution of the or of the at least one selected and assigned machining order a45 and as a function of first state s4#1. Attained state s5#1 is incorporated into the tree in the event it is not yet represented there. This means that counters n(s5#1) and n(s5#1, a) are initialized for state s5#1. Counters n(s5#1) and n(s5#1, a) (for all a) are each initialized to 0. In step 112, counters n(s5#1) and n(s5#1, a) are then each increased by 1, a* being the action selected in s5#1. An assignment of the at least one machining order a45 includes, for example, placing the at least one machining order a45 in a priority queue of a processing resource in second state s5#1 of representation T. Second subsequent state s5#1 is ascertained, for example, by a simulation of the industrial system taking first state s4#1 and placed selected machining order a45 into account. The simulation includes the execution of the machining orders queued in the respective priority queue of the respective processing resource.

A respective machining order includes an indication of the object or workpiece to be machined, a machining state such as, for example, ‘waiting to be processed,’ ‘in process’ or ‘finished’ and a priority for starting machining, which is generally related and/or related to a type of processing resource.

A step 112 includes a return of the result of the simulation, which includes, for example, a successful execution of the predefined plurality of machining orders along selected states s5#1, s4#1, s#3#3, s2#1, s1#1, i.e., if it is established in step 110 that the plurality of machining orders in ascertained second state s5#1 are executed. This phase of the search updates the search tree according to representation T with the pieces of information obtained. In the process, the selected states are visited in reverse order in the direction of start state s1#1, i.e., starting with the leaf in terms of second state s5#1, the exploration term and the exploitation term being updated.

The Monte Carlo search method includes an analysis of the most promising actions, the Monte Carlo search tree being expanded on the basis of random samplings in the search tree. The application of the Monte Carlo tree search in games is based on numerous playouts, which are also referred to as roll-outs. In each roll-out, the game is played out to the end by selecting moves at random and on the basis of the previously ascertained recommendation. The end result of each playout is then used to weight the nodes in the Monte Carlo search tree, so that better nodes/states are more likely to be selected in future playouts.

The method of using playouts consists of applying the playouts after each permissible move and to then select the move that resulted in the best assessment. The best assessment includes, for example, the most number of simulations. Each search round of the Monte Carlo tree search is made up of four steps: selection, expansion, simulation and backpropagation/return.

In the backpropagation phase/return phase according to step 112, the result of the playout is used to update the pieces of information in the nodes on the path from the second state up to the start state.

The ascertainment of representation T of the industrial system includes a reduction of the weighting of the previously ascertained recommendation E via the number of simulations of each state associated with the recommendation. Thus, the reduction of the weighting of recommendation E is considered separately for each state, since each state s has a separate counter n(s). For example, the weighting of the previously ascertained recommendation in the selection of each machining order is initially great, which means that the expert recommendation initially plays a greater role in the ascertainment of the search tree. With an increased number of simulations, the weighting of the recommendation is reduced in order in this way to arrive at a faster convergence, i.e., at a completion of the machining orders with a reduced number of states. The weighting of recommendation E becomes less, the larger n(s) is.

If recommendation E is weighted weaker, i.e., beta becomes smaller, the exploration and exploitation terms are weighted more heavily as a result, see equation 1. The selection of the actions is then no longer influenced by the expert rule. Actions are selected with higher quality (exploitation term) and/or with smaller sample number (exploitation term).

In a step 114, an abort criterion for aborting the ascertainment of representation T is checked. Such an abort criterion includes, for example, the lapse of a time period for ascertaining or reaching a number of carried out simulations. The search rounds according to step 114 are repeated as long as machining orders are present. According to step 200, the move with the most carried out simulations is then selected as the final response in terms of manufacturing schedule P. A step 200 accordingly includes an ascertainment of manufacturing schedule P for the industrial system as a function of ascertained representation T. Manufacturing schedule P includes a temporal sequence of the assignments of machining orders to machines, i.e., to the physically available processing resources of the industrial system.

The method provided uses the Monte Carlo tree search with already existing dispatching rules in terms of recommendation E as search heuristics. It results in more adaptive solutions compared to pure dispatching rules, since the returned solution according to manufacturing schedule P may deviate from the dispatching rules.

The industrial system is, for example, a manufacturing system. For example, the method provided may be a manufacturing schedule P for the operation of parts or of an entire semiconductor plant. For example, it is determined in which machining sequence silicon wafers are fed to the various machining stages. Another example of the industrial system includes a packaging system.

The method provided may be utilized by receiving sensor signals of installed monitoring sensors of the processing machines of the plant (for example, power load, maintenance requirement) and via sensors, which monitor the position and state of orders within the plant (for example, silicon wafers), in order to calculate a control signal for controlling a physical system, for example, a computer-controlled robot, which loads the orders into available machines. This occurs via the analysis of the instantaneous state of the plant and via the simulation and optimization of possible machining orders.

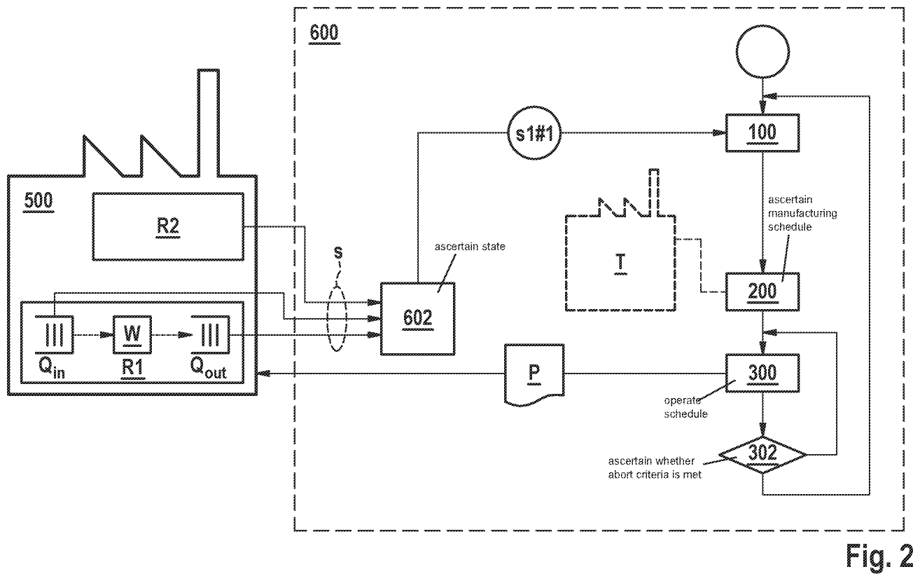

FIG. 2 schematically shows a block diagram including a device 600, which is configured to operate industrial system 500. Industrial system 500 includes processing resources R1 and R2, the structure of the processing resources being represented based on processing resources R1.

Processing resources R1 include a priority queue Qin, into which machining orders may be placed and an output queue Qout. A processing block W is located between the two queues Qin and Qout, which removes machining orders from the queue Qin based on their priority, subsequently processes them and after processing places them in queue Qout. Processing resources R1, R2 may, of course, also be connected in succession, in parallel to one another, i.e. interconnected in an arbitrarily complex manner. Further processing resources may, of course, also be present.

A block 602 ascertains an actual state S of individual processing resources R1, R2, the states of the individual components, i.e., of queues Qin, Qout as well as processing block W as well as the states of the individual machining orders being taken into account. This actual state S is fed as initial state s1#1 of representation T to block 100.

In a step 300, device 600 operates industrial system 500 as a function of manufacturing schedule P ascertained in steps 100 and 200.

A step 302 includes ascertaining that an abort criterion for operating 300 industrial system 500 is met. The abort criterion includes, for example, reaching a number of machining orders carried out with the aid of industrial system 500 and/or a lapse of a time period since the start of the processing of the manufacturing schedule.

Step 100 includes ascertaining a second representation T with state s1#1 of industrial system 500 upon meeting the abort criterion as the start state of second representation T. Step 200 includes ascertaining a second manufacturing schedule P for industrial system 500 as a function of ascertained second representation T. Step 300 includes operating industrial system 500 as a function of second manufacturing schedule P.

What is claimed is:

1. A method for an industrial system, comprising the following steps:
ascertaining a representation of industrial system, the ascertaining of the representation including:
selecting a first state of the representation,
selecting, based on the first state, at least one machining order from a plurality of machining orders as a function of the first state of the representation and as a function of at least one previously ascertained recommendation,
ascertaining a second state as a subsequent state of the first state via a simulation of the second state as a function of the at least one selected machining order and as a function of the first state; and
ascertaining a manufacturing schedule for the industrial system as a function of the ascertained representation.

2. The method as recited in claim 1, further comprising:
operating the industrial system as a function of the ascertained manufacturing schedule.

3. The method as recited in claim 2, further comprising:
ascertaining that an abort criterion for operating the industrial system is met;
ascertaining a second representation having a state of the industrial system upon meeting the abort criterion as a start state of the second representation;
ascertaining a second manufacturing schedule for the industrial system as a function of the ascertained second representation; and
operating the industrial system as a function of the second manufacturing schedule.

4. The method as recited in claim 1, wherein the ascertaining of the representation of the industrial system further includes:
assigning the selected at least one machining order to a processing resource of the representation of the industrial system as a function of a state of the processing resource of the representation in the first state.

5. The method as recited in claim 1, wherein the ascertaining of the representation of the industrial system further includes:
returning a result of the simulation along with selected states.

6. The method as recited in claim 1, wherein the ascertaining of the representation of the industrial system further includes:
reducing a weighting of the previously ascertained recommendation when selecting the at least one machining order with an increasing number of simulations of a respective state of the representation.

7. The method as recited in claim 1, wherein the selecting of the machining order includes:
selecting the machining order from the plurality of machining orders as a function of the previously ascertained recommendation and as a function of a criterion, the criterion including at least one of the following criteria:
an increased number of carried out simulations;
an increased average total reward.

8. The method as recited in claim 1, wherein the ascertained first and second states of the representation are part of a Monte Carlo search tree.

9. A device for an industrial system which is configured to:
ascertain a representation of the industrial system, the ascertainment of the representation including:
selection of a first state of the representation,
selection of, based on the first state, at least one machining order from a plurality of machining orders as a function of the first state of the representation and as a function of at least one previously ascertained recommendation,
ascertainment of a second state as a subsequent state of the first state via a simulation of the second state as a function of the at last one selected machining order and as a function of the first state; and
ascertain a manufacturing schedule for the industrial system as a function of the ascertained representation.

10. The device as recited in claim 9, wherein the device is further configured to operate the industrial system as a function of the ascertained manufacturing schedule.

11. A method for an industrial system, the method comprising:
providing a device for the industrial system which is configured to:
ascertain a representation of the industrial system, the ascertainment of the representation including:
selection of a first state of the representation,
selection of, based on the first state, at least one machining order from a plurality of machining orders as a function of the first state of the representation and as a function of at least one previously ascertained recommendation,
ascertainment of a second state as a subsequent state of the first state via a simulation of the second state as a function of the at last one selected machining order and as a function of the first state; and
ascertain a manufacturing schedule for the industrial system as a function of the ascertained representation; and
using the device to ascertain the manufacturing schedule.
